(19) United States
(12) Patent Application Publication
(10) Pub. No.: US 2024/0264245 A1
(43) Pub. Date: Aug. 8, 2024

(54) ENERGY STORAGE APPARATUS AND METHOD FOR DETERMINING CONNECTION STATE

(71) Applicant: GS Yuasa International Ltd., Kyoto-shi, Kyoto (JP)

(72) Inventors: Satoshi KUNITA, Kyoto-shi, Kyoto (JP); Yuki IMANAKA, Kyoto-shi, Kyoto (JP)

(21) Appl. No.: 18/563,192

(22) PCT Filed: Apr. 13, 2022
(86) PCT No.: PCT/JP2022/017670

§ 371 Date: Nov. 21, 2023

(30) Foreign Application Priority Data
May 24, 2021 (JP) 2021-086791

(51) Int. Cl. G01R 31/54; B60R 16/033; H01M 50/583; H02J 7/00

(52) U.S. Cl. CPC G01R 31/54; B60R 16/033; H01M 50/583; H02J 7/0036

(57) ABSTRACT

An energy storage apparatus for a moving body includes: an energy storage cell; an external terminal for connecting the energy storage apparatus to the moving body; a current interruption device provided to a connection line that connects the energy storage cell and the external terminal, the current interruption device being configured to interrupt a current of the energy storage cell; a first parallel circuit connected in parallel to the current interruption device and the energy storage cell; and a control unit, wherein the first parallel circuit includes a resistor and a switch that is connected to the resistor in series, and the control unit is configured to determine, in a state where the current interruption device is switched to an open state and the switch of the first parallel circuit is switched to a closed state, an electrical connection state of the energy storage apparatus to the moving body based on a current that flows from the moving body via the external terminal and the first parallel circuit.

### CROSS REFERENCE TO RELATED APPLICATIONS

This application is a National Stage Application, filed under 35 U.S.C. § 371, of International Application No. PCT/JP2022/017670, filed Apr. 13, 2022, which international application claims priority to and the benefit of Japanese Application No. 2021-086791, filed May 24, 2021; the contents of both of which are hereby incorporated by reference in their entirety.

### BACKGROUND

### Technical Field

One aspect of the present invention relates to a technique for determining an electrical connection state between an energy storage apparatus and a moving body.

### Description of Related Art

A battery mounted on a moving body such as an automobile includes a current interruption device as one of protective devices. When a certain abnormality is detected, a current interruption device is switched to an open state so as to interrupt a current. Accordingly, the battery can be protected (see Patent document JP-A-2017-5985).

### BRIEF SUMMARY

When an energy storage apparatus is disconnected from a moving body, the supply of electricity from the energy storage apparatus to the moving body is stopped. Accordingly, there has been a demand for the determination of a connection state that determines whether or not the energy storage apparatus is connected to the moving body.

According to an aspect of the present invention, there is provided a technique that determines a connection state of an energy storage apparatus to a moving body by focusing on a current that flows into the energy storage apparatus from a moving body.

An energy storage apparatus for a moving body according to one aspect of the present invention includes: an energy storage cell; an external terminal for connecting the energy storage apparatus to the moving body; a current interruption device that is provided on a connection line connecting the energy storage cell and the external terminal and interrupts a current of the energy storage cell; a first parallel circuit connected in parallel to the current interruption device and the energy storage cell; and a control unit. The first parallel circuit includes a resistor and a switch that is connected to the resistor in series. The control unit is configured to determine, in a state where the current interruption device is switched to an open state and the switch of the first parallel circuit is switched to a closed state, an electrical connection state of the energy storage apparatus to the moving body based on a current that flows from the moving body via the external terminal and the first parallel circuit.

The present technology can be applied to the method for determining the electrical connection state of the energy storage apparatus to the moving body.

According to the above aspect, it is possible to determine the electrical connection state of the energy storage apparatus to the moving body.

### BRIEF DESCRIPTION OF THE FIGURES

FIG. 1 is a side view of an automobile.

FIG. 2 is an exploded perspective view of a battery.

FIG. 3 is a plan view of a secondary battery cell.

FIG. 4 is a cross-sectional view taken along a line A-A in FIG. 3.

FIG. 5 is a block diagram of the battery.

FIG. 6 is a block diagram illustrating a charging path and a discharging path in the battery.

FIG. 7 is a block diagram illustrating a current path at the time of connection.

FIG. 8 is a block diagram illustrating a current path at the time of disconnection.

FIG. 9 is a table illustrating a control pattern of switches.

FIG. 10 is a table illustrating a current measurement values at the time of connection and the current measurement value at the time of disconnection.

FIG. 11 is the flow of determination.

FIG. 12 is a block diagram of a battery.

FIG. 13 is a block diagram of a battery.

### DETAILED DESCRIPTION OF VARIOUS EMBODIMENTS

The overall configuration of an energy storage apparatus for a moving body will be described.

The energy storage apparatus includes: an energy storage cell; an external terminal for connecting the energy storage apparatus to the moving body; a current interruption device provided to a connection line that connects the energy storage cell and the external terminal, the current interruption device being configured to interrupt a current of the energy storage cell; a first parallel circuit connected in parallel to the current interruption device and the energy storage cell; and a control unit. The first parallel circuit includes a resistor and a switch that is connected to the resistor in series. The control unit determines, in a state where the current interruption device is switched to an open state and the switch of the first parallel circuit is switched to a closed state, an electrical connection state of the energy storage apparatus to the moving body based on a current that flows from the moving body via the external terminal and the first parallel circuit.

In this configuration, by closing the switch of the first parallel circuit and by opening the current interruption device, it is possible to form a current path that allows a current to flow therethrough while bypassing the energy storage cell inside the energy storage apparatus. Accordingly, in a case where the moving body and the energy storage apparatus are electrically connected to each other, a current flows from the power supply mounted on the moving body via the path formed of the external terminal and the first parallel circuit, and the current returns to the moving body via the external terminal. Accordingly, it is possible to determine the electrical connection state of the energy storage apparatus to the moving body based on a current that flows from the moving body via the external terminal and the first parallel circuit in a state where the current interruption device is switched to an open state and the switch of the first parallel circuit is switched to a closed state. The energy storage apparatus has a function of determining the connection state. Accordingly, the energy storage apparatus can detect an abnormality in the connection state at an early stage compared to a case where the energy storage apparatus has no such function. Accordingly, it is possible to provide a highly reliable energy storage apparatus.

In a case where the energy storage cell is in a no-current state (a state in which the energy storage cell is neither charged nor discharged) in a state where the switch of the first parallel circuit is switched to an open state and the current interruption device is switched to a closed state, there is a high possibility that the energy storage apparatus is not connected to the moving body. However, there is a possibility that the energy storage cell is brought into a no-current state due to a voltage balance between a terminal voltage of the energy storage apparatus and an output voltage of the power supply mounted on the moving body.

In a case where a no-current state of the energy storage cell continues for a predetermined period in a state where the switch of the first parallel circuit is switched to an open state and the current interruption device is switched to a closed state, the control unit may change over the switch of the first parallel circuit into a closed state, and may change over the current interruption device to an open state, and may determine an electrical connection state of the energy storage apparatus to the moving body based on a current that flows from the moving body via the external terminal and the first parallel circuit.

In such a configuration, in a case where the energy storage cell is in a no-current state, the control unit does not immediately determine that the energy storage apparatus is disconnected, and switches the switch of the first parallel circuit to a closed state and switches the current interruption device to an open state.

In a case where the energy storage cell is in a no-current state due to a voltage balance between a terminal voltage of the energy storage cell and an output voltage of the power supply mounted on the moving body, when the control unit switches the switch of the first parallel circuit to a closed state and switches the current interruption device to an open state, a current flows from the moving body to the energy storage apparatus via the external terminal and the first parallel circuit. Due to the flow of a current that flows from the moving body to the energy storage apparatus, it is possible to confirm that the energy storage apparatus is connected to the moving body. Accordingly, it is possible to suppress the occurrence of erroneous determination that the energy storage apparatus is disconnected from the moving body. By suppressing the occurrence of the erroneous determination of the connection state of the energy storage apparatus, it becomes unnecessary for a user to perform an operation of confirming the connection state that is basically unnecessary, and it is possible to provide a highly reliable energy storage apparatus.

The energy storage apparatus may further include a current sensor within a range from the external terminal to a parallel connection point of the first parallel circuit with respect to a connection line that connects the external terminal and the energy storage cell.

In such a configuration, the current sensor can be used not only for determining the connection state of the energy storage apparatus to the moving body but also for measuring a current of the energy storage cell.

The energy storage apparatus may include a second parallel circuit that is connected in parallel to the current interruption device, and the second parallel circuit may include a diode where a discharging direction of the energy storage cell is set as a forward direction, and a switch that is connected in series with the diode.

With this configuration, by closing the switch of the second parallel circuit while the current interruption device is open, electricity can be supplied from the energy storage cell to the moving body via the second parallel circuit. Accordingly, it is possible to determine the electrical connection state of the energy storage apparatus to the moving body without causing a power fail (power supply loss) of the moving body.

The moving body is a vehicle. In a case where a no-current state of the energy storage cell continues for a predetermined period during operation of the vehicle, the control unit may change over the current interruption device into an open state, the switch of the first parallel circuit into a closed state, and the switch of the second parallel circuit into a closed state, and may determine an electrical connection state of the energy storage apparatus to the vehicle based on a current that flows from the vehicle via the external terminal and the first parallel circuit.

The energy storage cell frequently performs charging and discharging of electricity during the operation of the vehicle. Accordingly, in a case where a no-current state (a state where neither charging of electricity nor discharging of electricity is performed) continues for a predetermined period, there is a high possibility that the energy storage apparatus is disconnected from the vehicle. With this configuration, it is possible to determine the electrical connection state of the energy storage apparatus without causing a power fail (power loss) during the operation of the vehicle. With this configuration, the connection state of the energy storage apparatus can be confirmed during the operation of the vehicle. Accordingly, the safety of the vehicle can be effectively enhanced.

In a case where the control unit detects disconnection of the energy storage apparatus during the operation of the vehicle, the control unit may notify the disconnection of the energy storage apparatus to the vehicle.

With this configuration, it is possible to notify that the energy storage apparatus is not connected to the vehicle from the energy storage apparatus to the vehicle. Accordingly, it is possible to urge a driver to take an emergency action such as emergency stop of the vehicle.

In a case where the control unit detects disconnection of the energy storage apparatus during the operation of the vehicle, the control unit may determine that a cable that electrically connects the energy storage apparatus and the vehicle is detached or disconnected.

With such a configuration, it is possible to notify a user that the cause of the disconnection of the energy storage apparatus is the detachment or the disconnection of the cable. Once the cause of the disconnection is found, the reconnection work of the energy storage apparatus to the vehicle can be easily performed and hence, maintainability is increased.

The control unit may determine whether the vehicle is operating or not via the communication with the vehicle. In this configuration, the state of the vehicle is determined using the communication function. Accordingly, the operation or non-operation of the vehicle can be determined without relying on the electrical connection state (the connection state via the external terminal) between the vehicle and the energy storage apparatus.

The control unit may, in a case where the no-current state of the energy storage cell continues for a predetermined period during the operation of the drive device of the vehicle, may change over the current interruption device to an open state, the switch of the first parallel circuit to a closed state, and the switch of the second parallel circuit to a closed state, and may determine an electrical connection state of the energy storage apparatus to the vehicle based on a current that flows from the moving body via the external terminal and the first parallel circuit.

Compared with the non-operation period, in the operation period of the drive device, the detachment or the disconnection of the cable due to vibration is likely to occur and hence, there is a high possibility that the energy storage apparatus is disconnected. With the above-described configuration, it is possible to detect, at an early stage, a connection abnormality of the energy storage apparatus which occurs during an operation of the drive device.

A cable that electrically connects the energy storage apparatus to the vehicle may be fastened to the external terminal by a bolt. In the case of fastening using the bolt, there is a possibility that the bolt is loosened due to vibration of the vehicle so that the cable is detached. By applying the present technology, a connection failure of the energy storage apparatus due to the detachment of the cable can be detected and hence, the safety of the vehicle can be enhanced.

### First Embodiment

### 1. Description of Battery 50

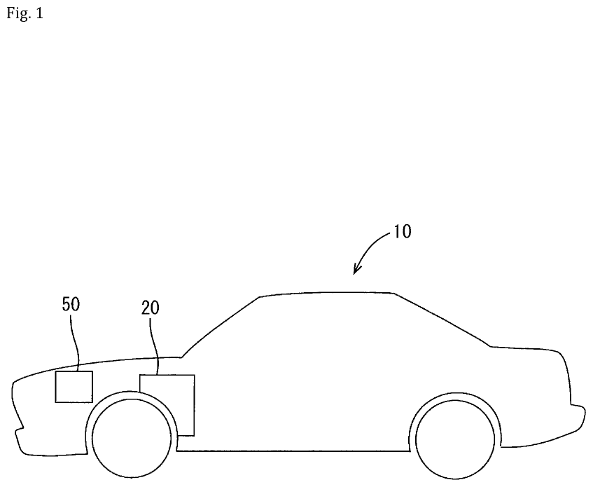

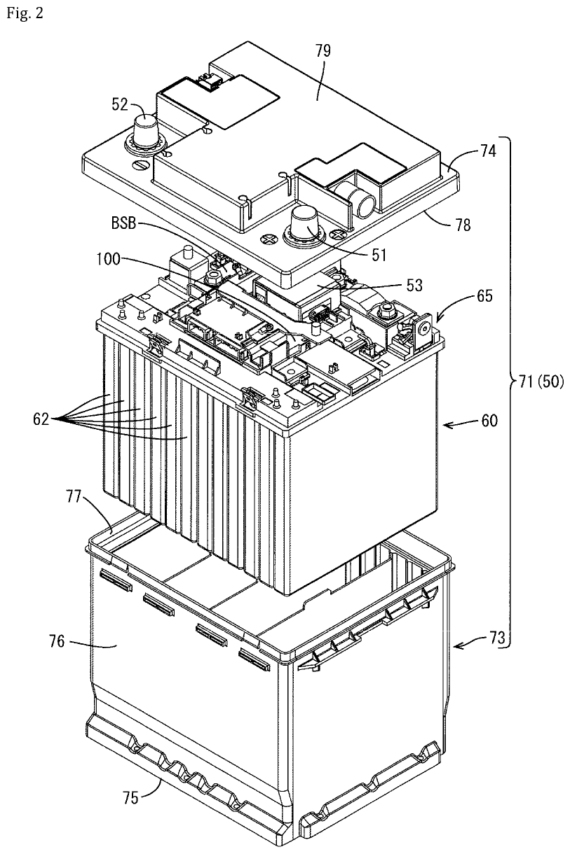

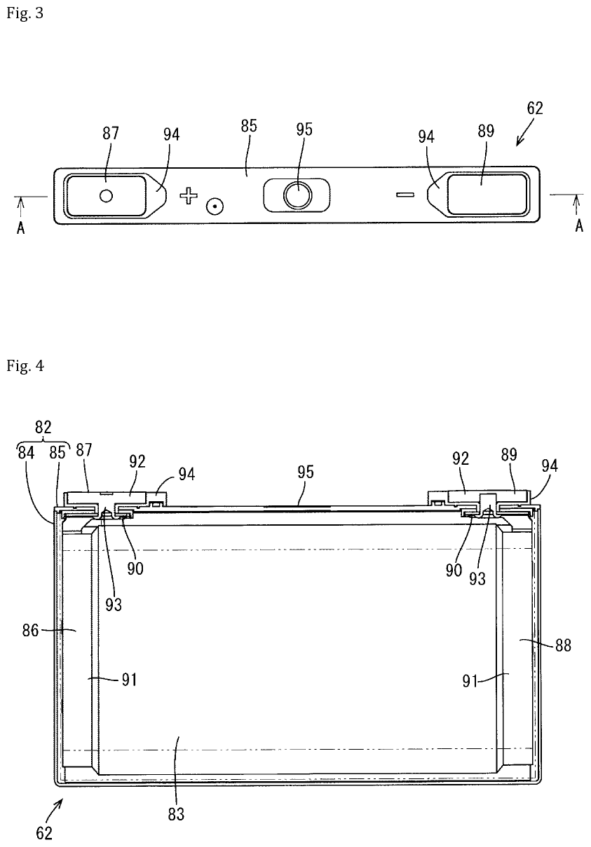

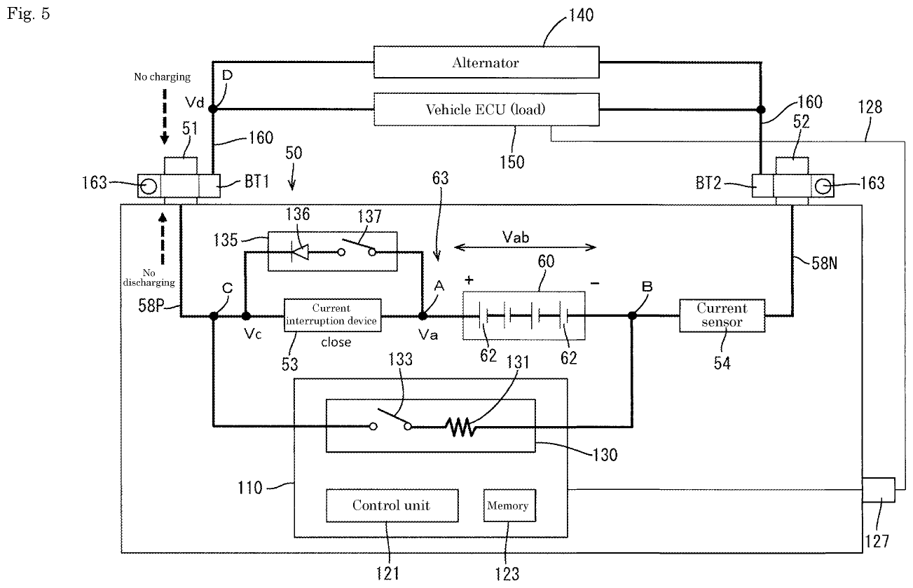

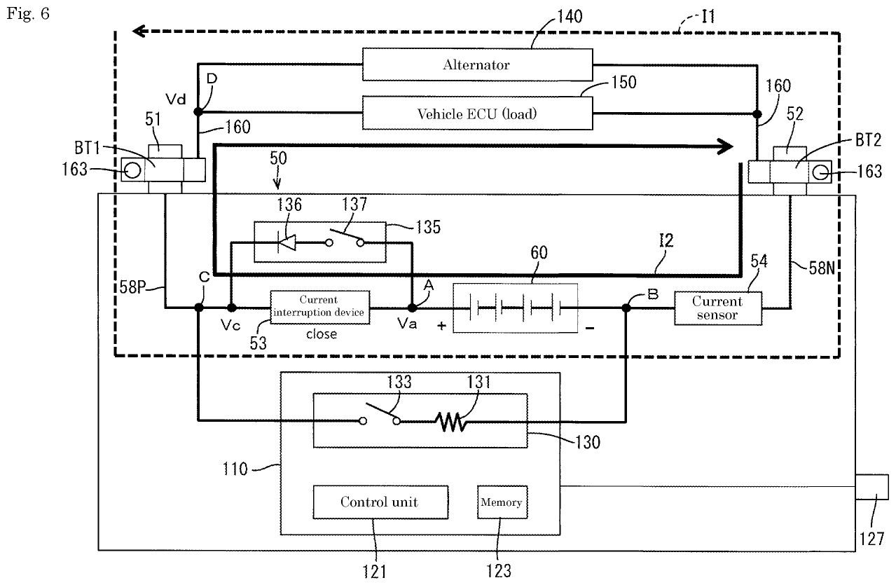

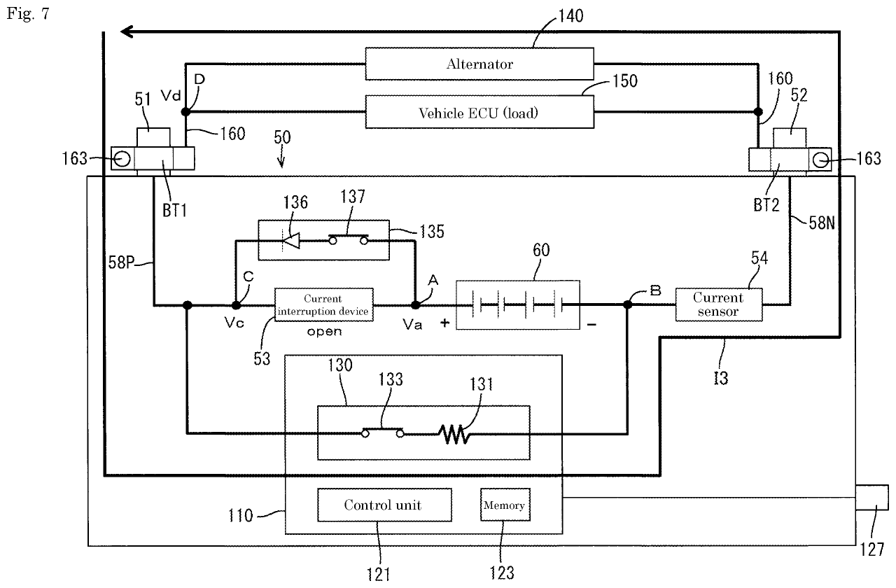

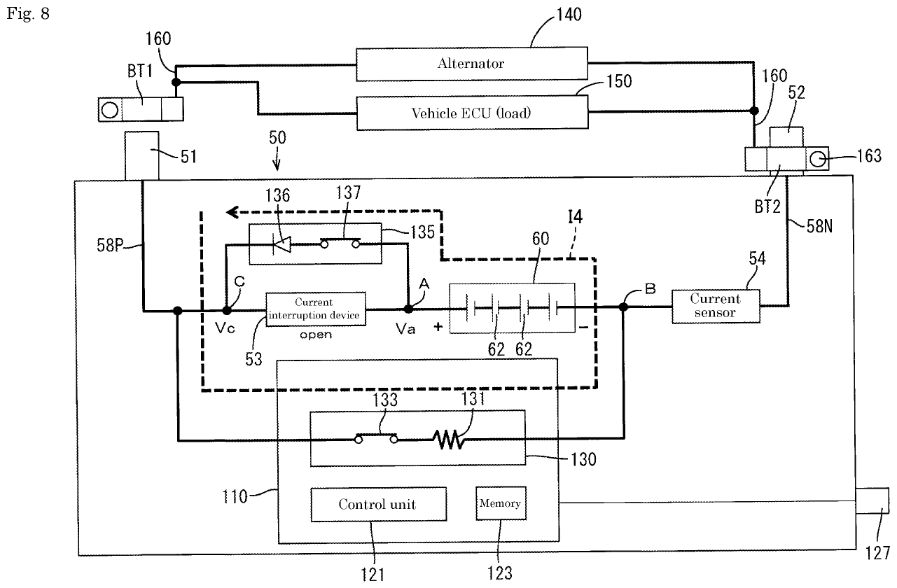

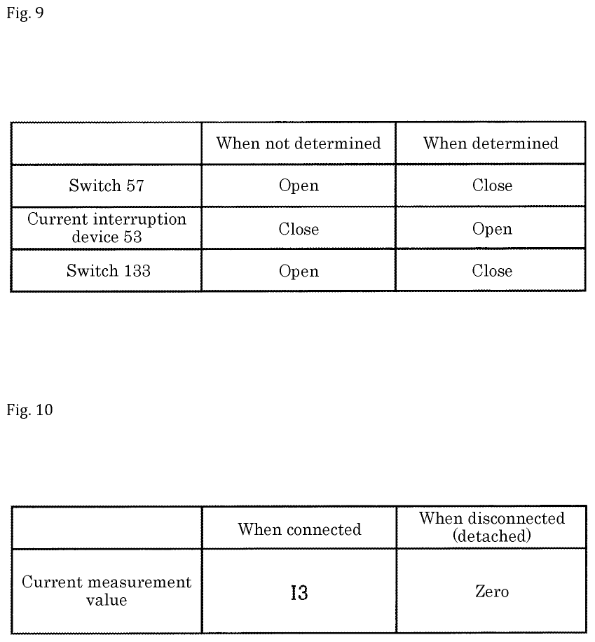

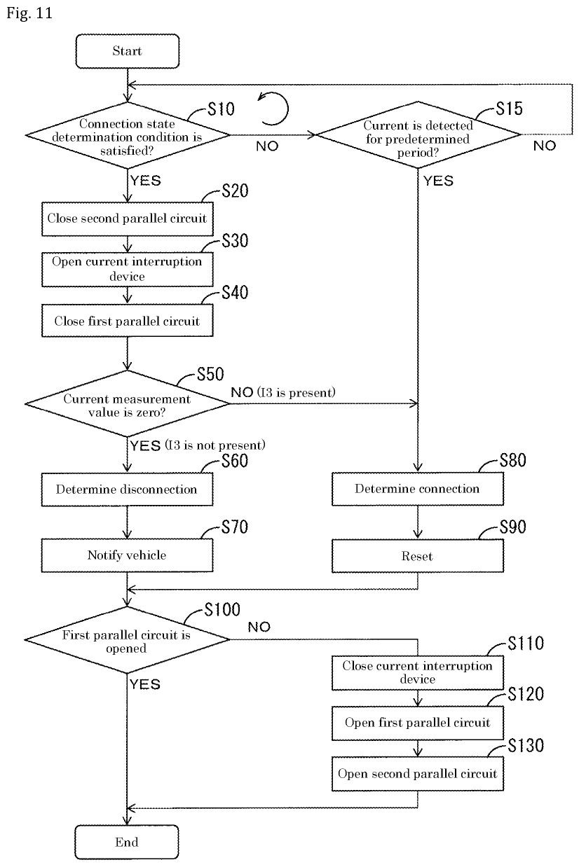

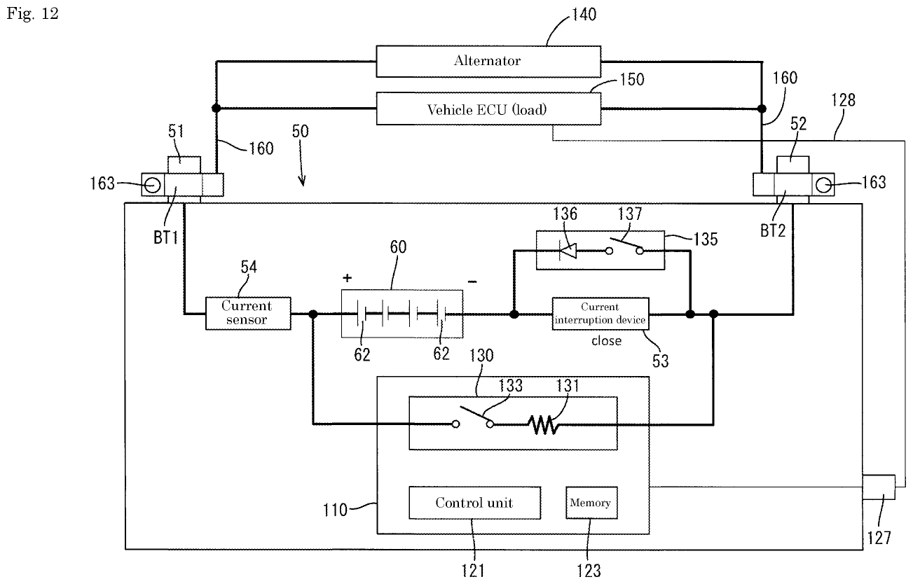

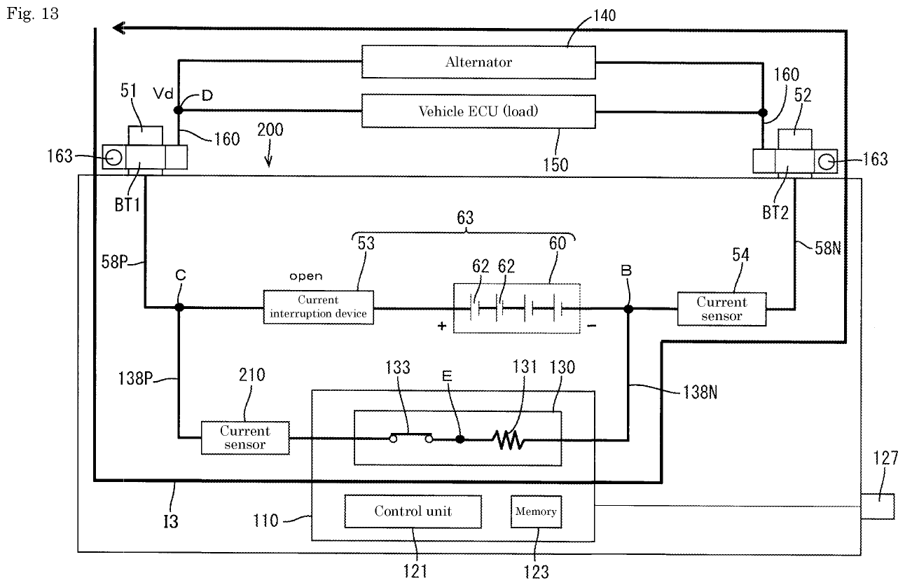

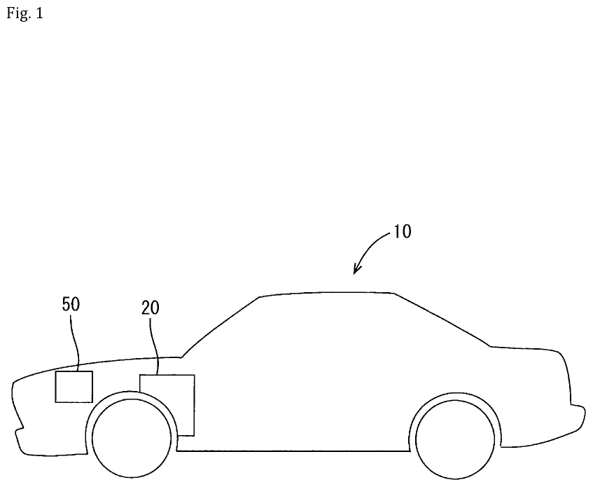

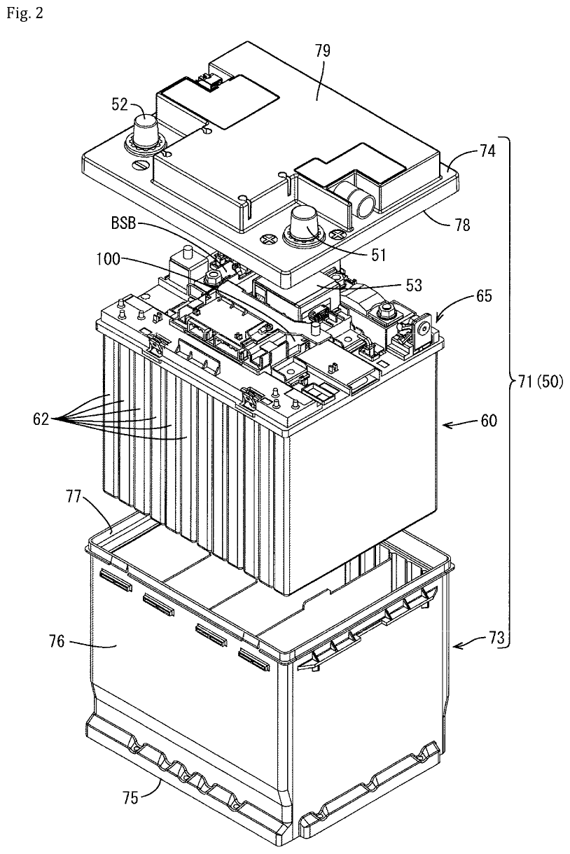

As illustrated in FIG. 1, an engine 20 and a battery 50 used at the time of starting the engine 20 or the like are mounted on an automobile 10 (an example of a moving body). The battery 50 is an example of “energy storage apparatus”. As illustrated in FIG. 2, the battery 50 includes an assembled battery 60, a circuit board unit 65, and a container 71.

The container 71 includes a body 73 made of a synthetic resin material, and a lid body 74. The body 73 has a bottomed cylindrical shape. The body 73 includes a bottom surface portion 75 and four side surface portions 76. An upper opening portion 77 is formed at an upper end portion of the body 73 by four side surface portions 76.

The container 71 contains the assembled battery 60 and a circuit board unit 65. The circuit board unit 65 is disposed above the assembled battery 60.

The lid body 74 closes the upper opening portion 77 of the body 73. An outer peripheral wall 78 is formed on a periphery of the lid body 74. The lid body 74 has a protruding portion 79 having an approximately T shape as viewed in a plan view. On a front portion of the lid body 74, a positive external terminal 51 is fixed to one corner portion, and a negative external terminal 52 is fixed to the other corner portion.

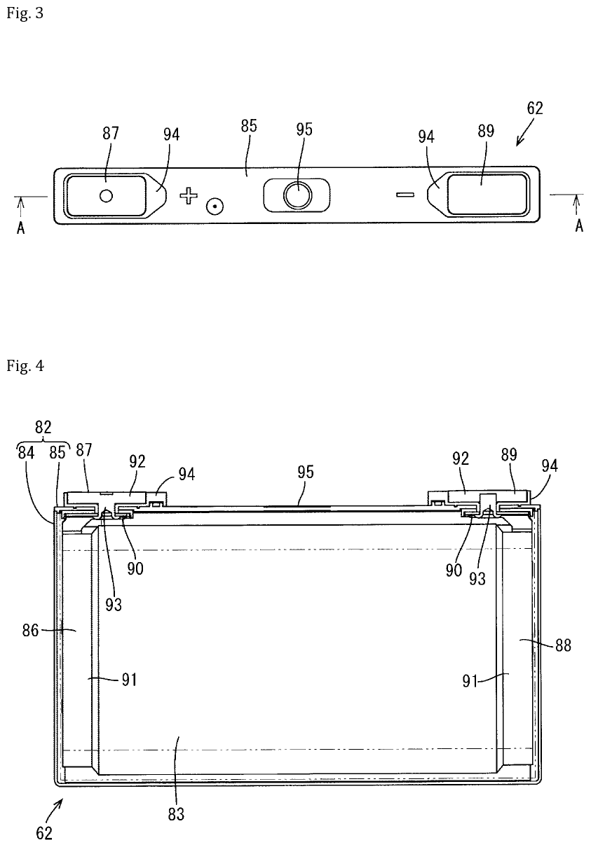

As illustrated in FIG. 3 and FIG. 4, the secondary battery cell 62 is configured such that an electrode assembly 83 is accommodated in a case 82 having a rectangular parallelepiped shape together with a nonaqueous electrolyte. The secondary battery cell 62 is, as an example, a lithium ion secondary battery cell. The case 82 includes a case body 84 and a lid 85 that closes an opening portion formed at an upper portion of the case body 84.

Although not illustrated in detail, the electrode assembly 83 is formed such that a separator formed of a porous resin film is disposed between a negative electrode element that is formed by applying an active material to a substrate formed of a copper foil, and a positive electrode element that is formed by applying an active material to a substrate formed of an aluminum foil. These elements all have a strip shape, and are wound in a flat shape so as to be accommodated in the case body 84 in a state where the position of the negative electrode element and the position of the positive electrode element are displaced toward opposite sides in the width direction with respect to the separator. The electrode assembly 83 may be an electrode assembly of a laminated type in place of an electrode assembly of a wound type.

A positive electrode terminal 87 is connected to the positive electrode element via a positive electrode current collector 86, and a negative electrode terminal 89 is connected to the negative electrode element via a negative electrode current collector 88. The positive electrode current collector 86 and the negative electrode current collector 88 are each formed of a flat plate-like pedestal portion 90 and a leg portion 91 extending from the pedestal portion 90. A through hole is formed in the pedestal portion 90. The leg portion 91 is connected to the positive electrode element or the negative electrode element.

The positive electrode terminal 87 and the negative electrode terminal 89 each include: a terminal body portion 92; and a shaft portion 93 protruding downward from a center portion of a lower surface of the terminal body portion 92. In such a configuration, the terminal body portion 92 and the shaft portion 93 of the positive electrode terminal 87 are integrally formed with each other using aluminum (a single material). In the negative electrode terminal 89, the terminal body portion 92 is made of aluminum, and the shaft portion 93 is made of copper. The negative electrode terminal 89 is formed by assembling the terminal body portion 92 and the shaft portion 93. The terminal body portion 92 of the positive electrode terminal 87 and the terminal body portion 92 of the negative electrode terminal 89 are disposed at both end portions of the lid 85 by way of gaskets 94 made of an insulating material. The terminal body portion 92 of the positive electrode terminal 87 and the terminal body portion 92 of the negative electrode terminal 89 are exposed outward from the gaskets 94.

The lid 85 has a pressure release valve 95. The pressure release valve 95 is positioned between the positive electrode terminal 87 and the negative electrode terminal 89. The pressure release valve 95 is released when an internal pressure in the case 82 exceeds a limit value so as to lower the internal pressure in the case 82. The secondary battery cell 62 is not limited to a prismatic cell, and may be a cylindrical cell or a pouch cell having a laminate case.

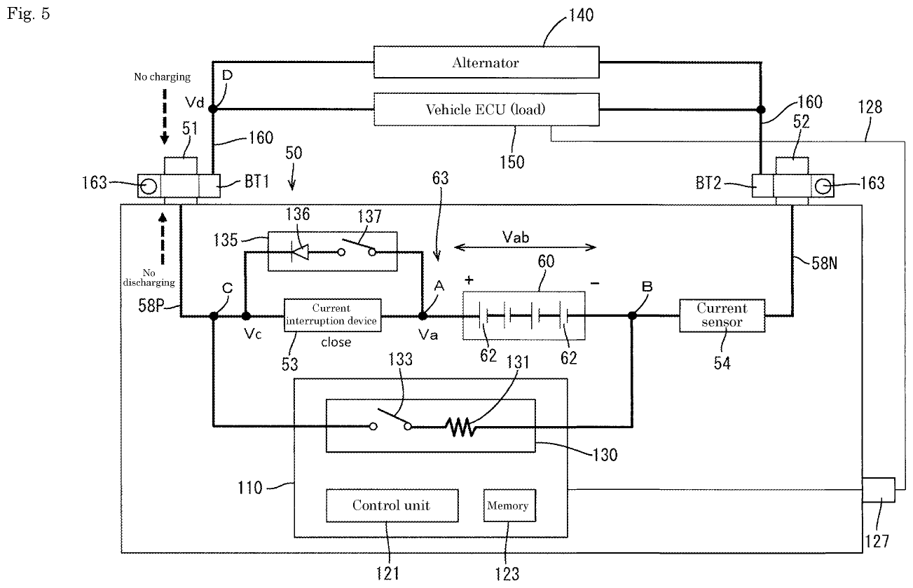

FIG. 5 is a block diagram illustrating the electrical configuration of the battery 50. The battery 50 includes an assembled battery 60, a current sensor 54, a current interruption device 53, a first parallel circuit 130, a second parallel circuit 135, and a management device 110. Va, Vc, and Vd in FIG. 5 indicate voltages at points A, C, and D on a current path.

The assembled battery 60 is formed of a plurality of secondary battery cells 62. Twelve secondary battery cells 62 are connected with each other in three parallels and four series. In FIG. 5, three secondary battery cells 62 that are connected in parallel are indicated by one battery symbol. The secondary battery cell 62 is an example of an “energy storage cell”. A rated voltage of the battery 50 is 12V. In place of connecting twelve secondary battery cells 62 in three parallels and four series, four secondary battery cells 62 may be connected in series to form one assembled battery 60.

The assembled battery 60, the current interruption device 53 and the current sensor 54 are connected in series via a power line 58P and a power line 58N. As the power lines 58P, 58N, a bus bar BSB (see FIG. 2) that is a plate-like conductive body made of a metal material such as copper can be used. The power line 58P and the power line 58N are examples of a “connection line”.

The power line 58P connects the positive external terminal 51 and a positive electrode of the assembled battery 60 to each other. The power line 58N connects the negative external terminal 52 and a negative electrode of the assembled battery 60 to each other. The external terminals 51, 52 are terminals for connecting the battery 50 with the automobile 10. A cable 160 is connected to the external terminals 51, 52 via battery terminals BT1, BT2. The battery terminals BT1, BT2 are fixed to distal ends of the cable 160, and are mounted on the external terminals 51, 52 using fastening components 163 such as bolts.

The current interruption device 53 is provided to the positive power line 58P. The current interruption device 53 may be a semiconductor switch such as an FET or a relay having a mechanical contact. The current interruption device 53 is normally closed, and is controlled to be closed in a normal operation state. When abnormality is detected in the battery 50, a current I of the assembled battery 60 can be interrupted by switching the current interruption device 53 from a closed state to an open state.

A second parallel circuit 135 is constituted of a diode 136 and a switch 137, and is connected in parallel to the current interruption device 53. The diode 136 sets the discharging direction of the assembled battery 60 as a forward direction. The switch 137 is connected to the diode 136 in series.

By closing the switch 137 in a state where the current interruption device 53 is switched to an open state, it is possible to prohibit charging of electricity to the battery 50 while enabling discharging of electricity to the automobile 10 via the second parallel circuit 135.

The second parallel circuit 135 can also be used for a diagnosis of a failure in the current interruption device 53. That is, by switching the current interruption device 53 from a closed state to an open state in a state where the switch 137 is switched to a closed state, a voltage difference Va-Vc between the points A and C is detected. That is, in a case where the current interruption device 53 is normally opened, the voltage difference Va-Vc is substantially equal to a diode voltage, and in a case where the current interruption device is fixed at the closed state, the voltage difference Va-Vc is substantially zero. Therefore, the presence or the non-presence of a failure can be diagnosed based on the voltage difference Va-Vc.

The current sensor 54 is provided to the negative power line 58N. The current sensor 54 measures a current I of the assembled battery 60.

The management device 110 is mounted on a circuit board 100 (see FIG. 2). The management device 110 includes a control unit 121, a memory 123 and the first parallel circuit 130.

The management device 110 is connected to a vehicle ECU 150 via a communication connector 127 and a communication line 128, and communicates with the vehicle ECU 150.

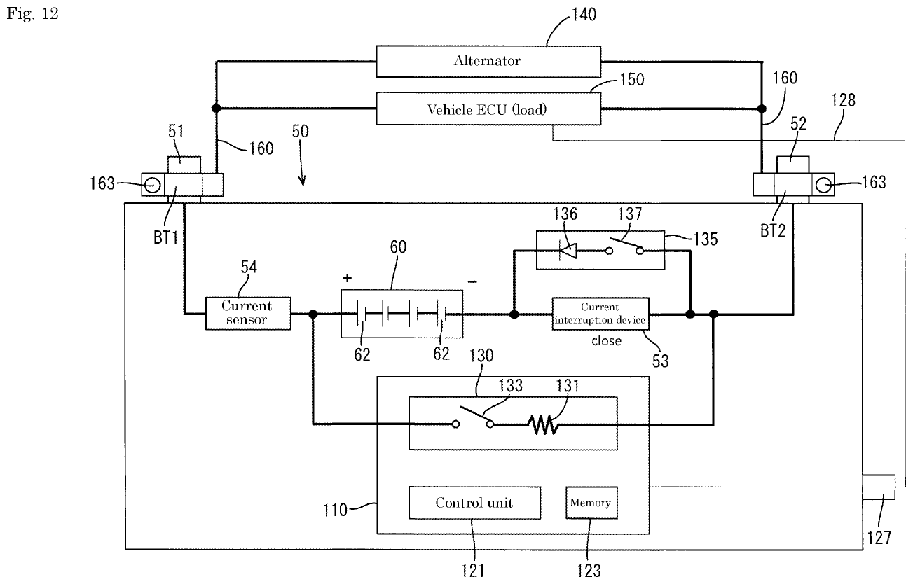

The management device 110 can receive information relating to an operation and a non-operation of the engine 20 that is a drive device from the vehicle ECU 150. Besides such information, the management device 110 can receive information relating to the state of the automobile 10 such as traveling, stopping, and parking. The communication line 128 is illustrated only in FIG. 5 and FIG. 12, and is omitted in other drawings.

The control unit 121 monitors the state of the battery 50 based on the outputs of the respective sensors. That is, the control unit 121 monitors a temperature T, a current I, and a total voltage Vab of the assembled battery 60.

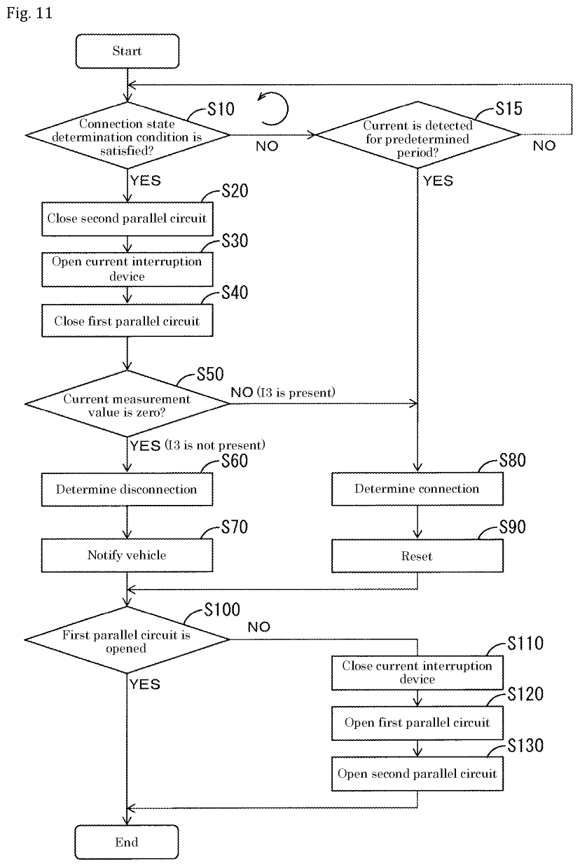

The memory 123 stores: a monitoring program for monitoring the state of the battery 50, a program for performing the flow for determining a connection state between the battery 50 and the automobile 10 via the external terminals 51 and 52 (FIG. 11); and data necessary for executing these programs. The program can be stored in a recording medium such as a CD-ROM thus enabling the transfer of the program. The program can also be distributed using an electric communication line.

The first parallel circuit 130 includes a resistor 131 and a switch 133. The switch 133 is connected in series to the resistor 131. One end of the first parallel circuit 130 is connected to a point C on the power line 58P (a connection point between the external terminal 51 and the current interruption device 53), and the other end of the first parallel circuit 130 is connected to a point B on the power line 58N (a connection point between the assembled battery 60 and the external terminal 52).

The first parallel circuit 130 is connected in parallel to the current interruption device 53 and the assembled battery 60. That is, the first parallel circuit 130 is connected in parallel to a series circuit 63 that is constituted of the current interruption device 53 and the assembled battery 60. The first parallel circuit 130 can also be used for discharging electricity of the assembled battery 60.

An alternator 140 and a vehicle electronic control unit (ECU) 150 are electrically connected to the two external terminals 51, 52 of the battery 50 via the cable 160. The vehicle ECU 150 is a vehicle control device.

The alternator 140 generates electricity by the power of the engine 20. The alternator 140 can charge electricity of 12V to the battery 50, and can also supply electricity to a vehicle load such as the vehicle ECU 150. The alternator 140 is an example of an “in-vehicle power supply”.

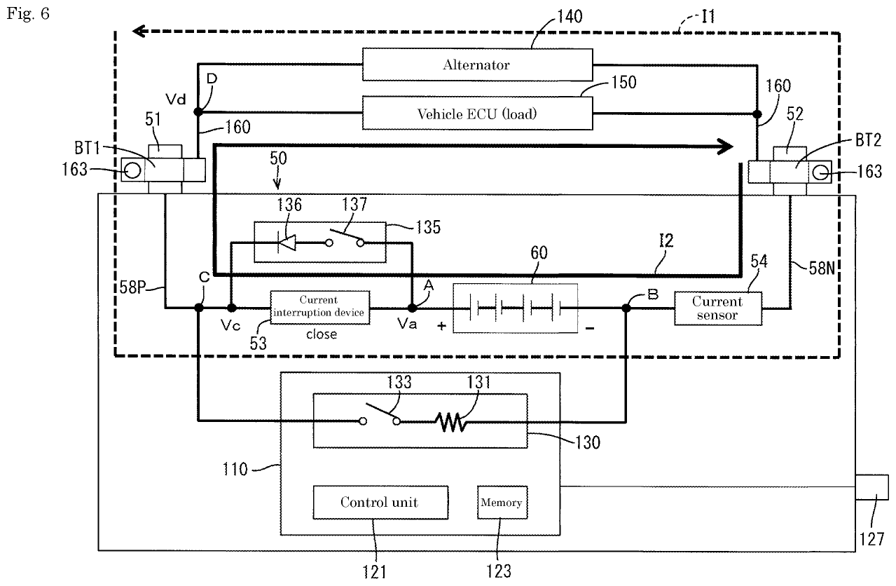

FIG. 6 illustrates a charging path and a discharging path of the battery 50. A charging current I1 flows to the assembled battery 60 via the alternator 140, the cable 160, the external terminal 51, and the current interruption device 53. The charging current I1 returns to the alternator 140 via the current sensor 54, the external terminal 52, and the cable 160 (a path indicated by a dotted line).

A discharge current I2 flows to the vehicle ECU (load) 150 via the assembled battery 60, the current interruption device 53, the external terminal 51, and the cable 160. The discharging current I returns to the assembled battery 60 via the cable 160, the external terminal 52, and the current sensor 54 (a path indicated by a bold line).

The first parallel circuit 130 and the second parallel circuit 135 are circuits for determining an electrical connection state between the automobile 10 and the battery 50. Usually, except for a case where the determination of the connection state is performed, both the switch 137 of the second parallel circuit 135 and the switch 133 of the first parallel circuit 130 are controlled to an open state.

### 2. Determination of Electrical Connection State Between Battery 50 and Automobile 10

In a case where the battery terminals BT1, BT2 are loosened due to vibration of the automobile 10 during traveling so that the cable 160 is detached from the external terminals 51, 52, the battery 50 is “disconnected” from the automobile 10. Accordingly, the supply of electricity from the battery 50 to the automobile 10 is interrupted.

As a method of determining the electrical connection state between the battery 50 and the automobile 10, the following method is considered. In the method, a current I of the assembled battery 60 is measured, and in a case where a no-current state (a case where the level of the current is equal to or below a predetermined value or substantially zero) of the assembled battery 60 continues for a predetermined period, it is determined that the battery 50 and the automobile 10 are not connected to each other.

However, when a terminal voltage Va (a voltage at the point A in FIG. 5) of the assembled battery 60 is equal to an output voltage Vd (the voltage at the point D in FIG. 5) of the alternator 140 (Va=Vd), the assembled battery 60 is brought into a no-current state, that is, as illustrated in FIG. 5, a state where neither charging of electricity nor discharging of electricity is performed.

Accordingly, in a case where the connection state between the battery 50 and the automobile 10 is determined based on only whether or not a noncurrent state of the assembled battery 60 continues for a predetermined period, there is a possibility of erroneous detection that the battery 50 and the automobile 10 are not connected to each other although the battery 50 is electrically connected to the automobile 10.

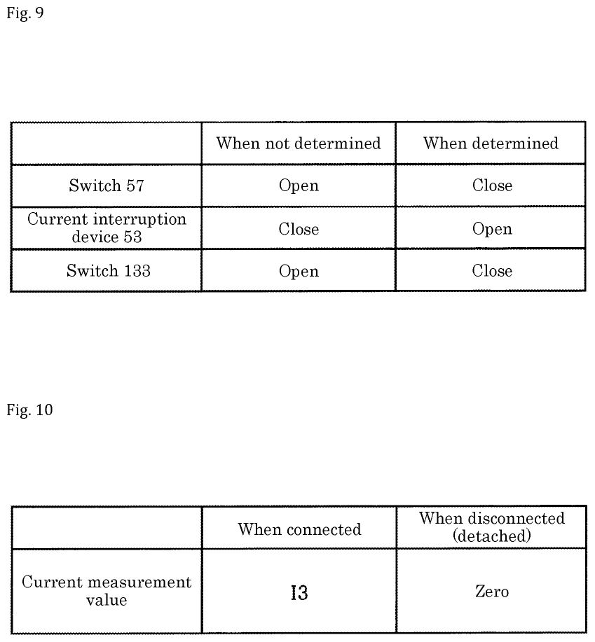

In this embodiment, in a case where no-current state of the assembled battery 60 continues for a predetermined period, the current interruption device 53, the first parallel circuit 130 and the second parallel circuit 135 are changed over as described below, and the electrical connection state between the automobile 10 and the battery 50 is determined by detecting a current that flows from the automobile 10 to the battery 50 (FIG. 9, FIG. 10).
(a) The current interruption device 53 is switched from a closed state to an open state.
(b) The switch 133 of the first parallel circuit 130 is switched from an open state to a closed state.
(c) The switch 137 of the second parallel circuit 135 is switched from an open state to a closed state.

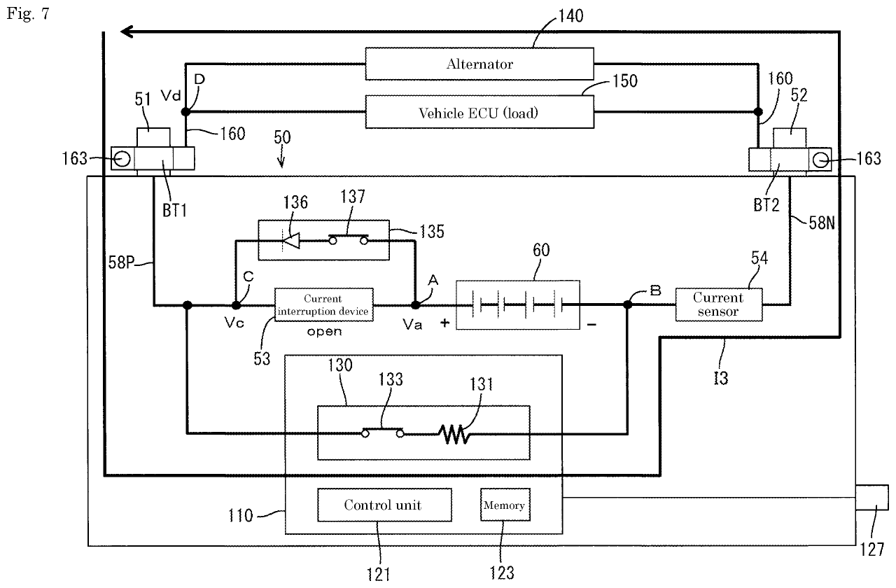

FIG. 7 illustrates a current path when the current interruption device 53, the first parallel circuit 130, and the second parallel circuit 135 are changed over in accordance with the operations (a) to (c) in a case where the battery 50 and the automobile 10 are normally connected to each other under a condition that the voltages Va, Vd satisfies the relationship of Va=Vd.

In a case where the connection state between the battery 50 and the automobile 10 is “normal”, an output current I3 generated by the alternator 140 flows from the automobile 10 to the battery 50. The output current I3 generated by the alternator 140 flows into the battery via the cable 160, the external terminal 51, and the first parallel circuit 130. The output current I3 returns to the alternator 140 via the current sensor 54, the external terminal 52, and the cable 160 (a path indicated by a bold line). In such a state, the voltages Va, Vd satisfy the relationship of Va=Vd and hence, the diode 136 is non-conductive, whereby the assembled battery 60 is brought into a state where the assembled battery 60 performs neither charging of electricity nor discharging of electricity.

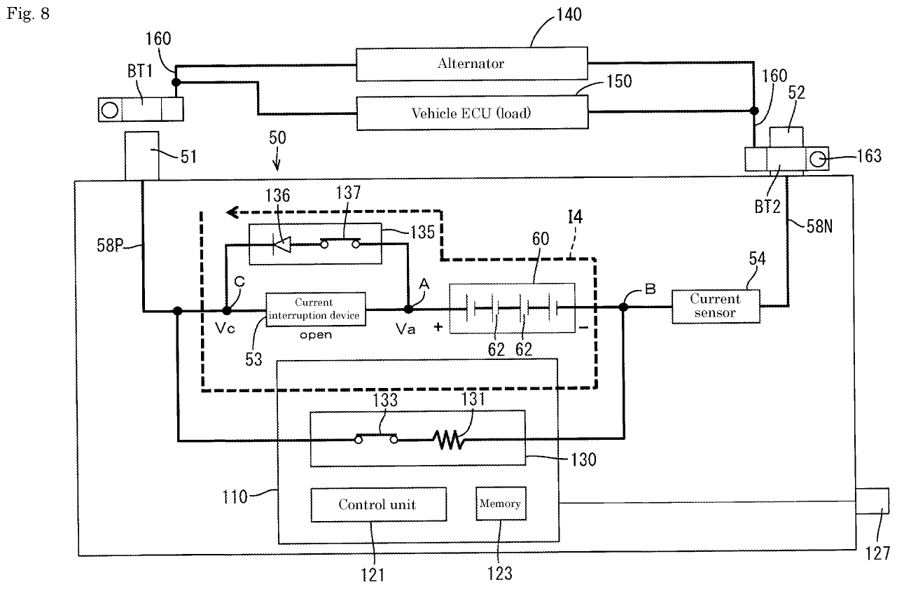

FIG. 8 illustrates a current path when the current interruption device 53, the first parallel circuit 130, and the second parallel circuit 135 are changed over in accordance with the conditions (a) to (c) in a case where the battery 50 is not connected to the automobile 10.

In a case where the battery 50 is “not connected”, the current I3 does not flow from the automobile 10 to the battery 50, and a discharge current I4 generated by the assembled battery 60 flows in the battery 50. The discharge current I4 flows via the second parallel circuit 135 and the first parallel circuit 130, and returns to the assembled battery 60 (a path indicated by a broken line).

In this manner, even in a case where a no-current state of assembled battery 60 continues for a predetermined period, so long as the battery 50 is connected to the automobile 10, by controlling the current interruption device 53, the first parallel circuit 130 and the second parallel circuit 135 in accordance with the operation (a) to (c), a current I3 flows into the battery from the alternator 140 that is an in-vehicle power supply via the external terminal 51, the first parallel circuit 130 and the external terminal 52.

Accordingly, even if the current I3 flows after switching the current interruption device 53, the first parallel circuit 130 and the second parallel circuit 135 to the conditions (a) to (c), it can be determined that the connection state between the battery 50 and the automobile 10 is “normal”. If the current I3 is not flowing, the battery 50 and the automobile 10 are “not connected”, and hence, it can be determined that the cable 160 is detached or the like.

The determination of the connection state of the battery 50 is not limited to the presence or non-presence of the current I3, and may be made based on the level of the current I3. For example, if the magnitude of the current I3 that flows from the automobile 10 to the battery 50 is known in a case where the connection state is normal, the connection state may be determined by determining the level of the actually measured current I3 using the known value of the current I3 as the reference. Provided that the determination of the connection state is performed based on the current I3, any determination method may be used.

FIG. 11 is a flow chart illustrating the determination flow for determining the electrical connection state of battery 50 to the automobile 10. The determination flow is constituted of 14 steps, that is, steps S10 to S130.

The control unit 121 usually preforms a control such that the current interruption device 53 takes a closed state, the switch 137 of the second parallel circuit 135 takes an open state, and the switch 133 of the first parallel circuit 130 takes an open state. Also at a point of time of starting the determination flow, the states of the current interruption device 53 and the switches 133, 137 are set at the above-mentioned states.

The control unit 121, after the automobile 10 is started, performs the determination flow in parallel to monitoring of the battery 50. First, the control unit 121 determines whether the determination condition of the connection state is satisfied (S10).

The determination condition of the connection state is a condition for determining whether or not the determination of the connection state (processing at step S20 and steps succeeding step S20) is performed. The determination condition may be the following three conditions, for example. The predetermined period is, as an example, substantially several minutes.
(1) The automobile 10 is in an operating state.
(2) The current interruption device 53 is in a closed state.
(3) A current value of the assembled battery 60 is equal to or below a predetermined value (substantially zero) for a predetermined period.

Whether or not the automobile 10 is in the operating state can be confirmed by communication with the vehicle ECU 150. In this embodiment, when the engine that is a drive device is being operated, it is determined that the automobile 10 is being operated. In case of a hybrid vehicle or an EV vehicle, a period during which the engine or a drive motor is being operated is determined as the operating state.

The condition (3) is satisfied in a case where the state where the assembled battery 60 performs neither charging electricity nor discharging electricity is continued. More specifically, the following two cases can be exemplified.
(3a) The battery 50 is disconnected (the cable 160 is detached).
(3b) A terminal voltage Va of the assembled battery 60 and an output voltage Vd of the alternator 140 agree with each other.

During an operation of the automobile 10, the battery 50 frequently performs charging of electricity and discharging of electricity. Usually, a charging current and a discharging current take values equal to or above a predetermined value and hence, the determination condition in step S10 is not satisfied.

During the operation of the automobile, when a current that takes a value equal to or above a predetermined value continuously flows for a predetermined period, the determination is “YES” in step S15. In this case, processing advances to step S80, and the control unit 121 determines that the connection state of the battery 50 is “normal”, that is, the battery 50 is electrically connected to the automobile 10.

When the battery terminals BT1, BT2 are loosened so that the cable 160 is detached during the operation of the automobile 10, the battery 50 is disconnected from the automobile 10. When the battery is disconnected from the automobile 10, the battery 50 is brought into a no-current state where the battery 50 performs neither charging of electricity nor discharging of electricity. Accordingly, when a predetermined period elapses after the battery 50 is disconnected, all conditions (1) to (3) are satisfied.

In a case where all conditions (1) to (3) are satisfied, the control unit 121 determines that the determination condition of the connection state is satisfied. In a case where the control unit 121 determines that the determination conditions of the connection state are satisfied (S10: YES), a command is given to the second parallel circuit 135 so that the control unit 121 switches the switch 137 from an open state to a closed state (S20).

Upon the detection of abnormality, (an external short circuit), the control unit 121 gives a command to the current interruption device 53 so as to change over the current interruption device 53 from a closed state to an open state (S30). Then, the control unit 121 gives a command to the first parallel circuit 130 so as to change over the switch 133 of the first parallel circuit 130 from an open state to a closed state (S40).

After the current interruption device 53 and the switches 133 and 137 are changed over, the control unit 121 determines whether or not a state (substantially zero state) in which the current measurement value measured by the current sensor 54 is equal to or less than a predetermined value continues for a certain period (S50). The predetermined period is, for example, substantially 30 seconds.

In a case where the state that a current measurement value is substantially zero continues for a predetermined period (no current I3), the control unit 121 determines that the battery 50 is “disconnected” to the automobile 10 (S60). The determination result is stored in the memory 123. As a cause of the disconnection, the detachment of the cable 160 due to loosening of the battery terminal BT is considered.

In a case where the control unit 121 detects “disconnected” of the battery 50 during the operation of the automobile 10 (S60), the control unit 121 notifies the occurrence of the abnormality (battery disconnected) to the vehicle ECU 150 (S70).

After the notification of the occurrence of the abnormality to the vehicle ECU 150, the control unit 121 confirms whether the switch 133 of the first parallel circuit 130 is controlled to an open state (S100). In a case where the switch 133 of the first parallel circuit 130 is controlled to an open state, the processing is finished at this stage.

In a case where the switch 133 of the first parallel circuit 130 is controlled to a closed state, the control unit 121 switches the current interruption device 53 from an open state to a closed state (S110).

Then, the switch 133 of the first parallel circuit 130 is switched from a closed state to an open state (S120), and, further, the switch 137 of the second parallel circuit 135 is switched from a closed state to an open state (S130). By switching the current interruption device 53 and the switches 137, 133, the current path in the battery returns to a state before the determination flow is performed.

Upon receiving the notification of occurrence of the abnormality (battery disconnection) from the battery 50, the vehicle ECU 150 notifies the abnormality to the driver by turning on a warning lamp. By the notification of the abnormality, it is possible to urge a driver to take an emergency action such as moving the automobile 10 to a safe place.

A case is described where, after the processing in S20 to S40 are performed, as a result of the determination of a current measurement value, a current I of a value equal to or above a predetermined value is measured (in a case where the determination is “NO” in S50).

In a case where a current I equal to or above predetermined value is measured (the current I3 being present), the control unit 121 determines that the battery 50 is electrically connected to automobile 10 (S80).

In a case where the control unit 121 determines that the battery 50 and the automobile 10 are connected to each other, the control unit 121 resets flags and values of timers and the like that are used in performing the determination flow (S90). The information on the result of determination stored in the memory 123 may be also reset together with the above resetting.

Then, the processing advances to S100. The subsequent processing is equal to the processing described above. By switching the current interruption device 53 and the switches 133, 137 in S110 to S130, the states of the current interruption device 53 and the switches 133, 137 return to an original state before the determination flow is performed.

After the automobile 10 is started, the control unit 121 can constantly confirm a connection state between the battery 50 and the automobile 10 by constantly performing the determination flow illustrated in FIG. 11 in parallel with the monitoring of the state of the battery 50. The determination flow is constantly performed even during the operation of the automobile 10. Accordingly, in a case where the detachment of the cable 160 or the like occurs so that the battery 50 is disconnected during the operation of the automobile 10, it is possible to detect the disconnection of the battery 50 early.

### 3. Description of Advantageous Effects

According to the present embodiment, it is possible to accurately determine a connection state between the battery 50 and the automobile 10 via the external terminals 51 and 52. That is, in a case where a terminal voltage Va of the assembled battery 60 and an output voltage Vd of the alternator 140 agree with each other so that the assembled battery 60 is in a no-current state, it is possible to suppress the occurrence of an erroneous determination that the connection state is “disconnected”.

According to the present embodiment, the switch 137 of the second parallel circuit 135 is switched to a closed state during the determination of the connection state. When the switch 137 is switched to a closed state, it is possible to supply electricity to the automobile 10 via the second parallel circuit 135. Accordingly, it is possible to determine the connection state between the battery 50 and the automobile 10 without causing a power fail (power supply loss) of the automobile 10.

### Other Embodiments

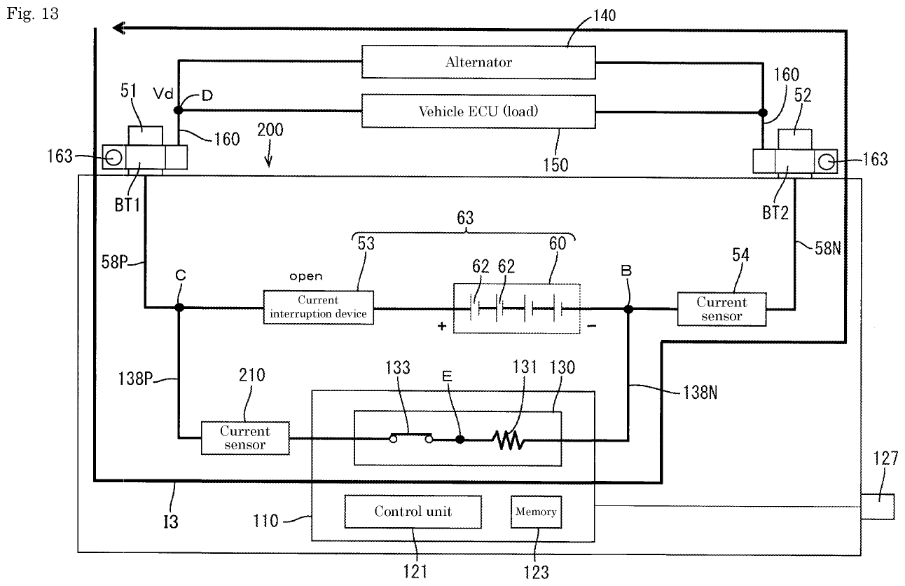

The present invention is not limited to the embodiments described with reference to the above description and drawings. For example, the following embodiments are also included in the technical scope of the present invention.
(1) The secondary battery cell 62 is not limited to a lithium ion secondary battery, and may be other nonaqueous electrolyte secondary batteries. A lead-acid battery cell may also be used. The secondary battery cells 62 are not limited to be connected in series and in parallel, and may be connected in series or may be formed of a single cell. A capacitor may be used in place of the secondary battery cell 62. The secondary battery cell and the capacitor are examples of an energy storage cell.
(2) In the above embodiment, the battery 50 is a battery for an automobile. However, the battery 50 is not limited to an automobile, and may be used in a motorcycle. The application of the battery 50 is not limited to vehicles such as automobiles and motorcycles. The present invention is broadly applicable to any objects other than vehicles provided that the objects to which the present invention is applicable are moving bodies such as ships, railways, and aircrafts. In this technique, the electrical connection state of the battery 50 to the moving body is determined based on a current that flows from the moving body to the battery 50. Accordingly, the moving body preferably has the configuration that includes at least a power supply other than the battery. The power supply may be a generator, a switching power supply, or a battery. The method of connecting the moving body and the battery to each other may be performed using a cable or a bus bar. Any connecting method may be used provided that the electrical connection is possible. In a case where a fastening component such as a bolt is used for fixing the cable or the bus bar, there is a concern that the cable or the bus bar is detached. Accordingly, the connection state may be checked by applying the present technology.
(3) In the above embodiment, the engine vehicle has been exemplified as an example of the automobile. The automobile is not limited to the engine vehicle, and may be a PHEV vehicle or a BEV vehicle. The in-vehicle power supply is not limited to the vehicle generator such as the alternator 140. In place of the alternator 140, a DC-DC converter may be used. The DC-DC converter is a device that steps down a voltage of an output of a battery for driving or a high-voltage battery, and supplies electricity of a stepped down voltage to a vehicle load or charges electricity of a stepped down voltage to a 12V battery 50.
(4) In the above embodiment, the current sensor 54 is disposed on the connection line 58N that connects the external terminal 52 and the assembled battery 60 within a range from the connection point B at which the first parallel circuit 130 is connected to the assembled battery 60 to the external terminal 52. The current sensor 54 may be disposed anywhere provided that the current sensor 54 is disposed on the connection line 58P, 58N that connects the external terminal 51, 52 and the assembled battery 60 within a range from the external terminal 51, 52 to the parallel connection point of the first parallel circuit 130. That is, in the case of the battery 50 illustrated in FIG. 5, the current sensor 54 may be disposed anywhere within the range from the external terminal 51 to the parallel connection point C at which the first parallel circuit 130 is connected to the current interruption device 53, or within a range from the parallel connection point B at which the first parallel circuit 130 is connected to the assembled battery 60 to the external terminal 52. By arranging the current sensor 54 in the above range, the current sensor 54 can be used not only for determination of the connection state but also for monitoring of a current in the assembled battery 60.
(5) In the above embodiment, the current interruption device 53 is disposed on the positive electrode of the assembled battery 60, and the current sensor 54 is disposed on the negative electrode of the assembled battery 60. Such arrangement may be reversed such that the current sensor 54 may be arranged on the positive electrode of the assembled battery 60 and the current interruption device 53 may be arranged on the negative electrode (see FIG. 12).
(6) In the above embodiment, as the case where the battery 50 is disconnected, the detachment of the cable 160 has been described. There is a concern that the cable 160 is disconnected due to the vibration of the engine itself or the vibration of the automobile 10 during traveling so that the battery 50 is disconnected from the automobile 10. In a case where the disconnection of the battery is detected during the operation of the automobile 10 (S60), the control unit 121 may determine that the cable 160 that connects the battery 50 and the automobile 10 is detached or disconnected. With such a configuration, it is possible to notify a user that the cause of the disconnection of the battery 50 is the detachment or the disconnection of the cable 160. Once the cause of the disconnection is found, the reconnection work of the battery 50 to the automobile 10 can be easily performed and hence, maintainability is increased.
(7) In the above embodiment, in a case where a no-current state (a state where neither charging of electricity nor discharging of electricity is performed) of the assembled battery 60 continues for a predetermined period, the connection state of the battery 50 to the automobile 10 is determined by switching the current interruption device 53 from a closed state to an open state, the switch 133 of the first parallel circuit 130 from an open state to a closed state, and the switch 137 of the second parallel circuit 135 from the open state to a closed state. Specifically, the connection state is determined based on whether or not the current I3 flows in the path from the automobile 10 via the external terminal 51 and the first parallel circuit 130. The determination of the connection state of the battery 50 to the automobile 10 is not limited to the case where a no-current state of the assembled battery 60 continues for a predetermined period, and other conditions may be used as triggers. For example, the determination may be performed in a case where a predetermined time has elapsed from the previous-time determination or after a failure of the current interruption device 53 is diagnosed using the second parallel circuit 135. For example, whether or not the current interruption device 53 is stuck closed is diagnosed by switching the current interruption device 53 from a closed state to an open state in a state where the switch 137 of the second parallel circuit 135 is switched to a closed state. Then, the connection state of the battery 50 to the automobile 10 may be determined by switching the switch 133 of the first parallel circuit 130 from an open state to a closed state. The determination of the connection state of the battery 50 may be performed regardless of whether or not the battery 50 has no current (a state whether neither charging of electricity nor discharging of electricity being performed). Provided that the current interruption device 53 is controlled to an open state at least at the time of determining the connection state, the current interruption device 53 may be brought into a closed state or into an open state at times besides the connection state determination time. In the same manner, provided that the first parallel circuit 130 and the second parallel circuit 135 are controlled to a closed state at least at the time of determining the connection state, the first parallel circuit 130 and the second parallel circuit 135 may be brought into a closed state or into an open state at times besides the connection state determination time.
(8) In the above embodiment, the second parallel circuit 135 is provided in parallel with the current interruption device 53. However, the second parallel circuit 135 may be eliminated. FIG. 13 is a block diagram of a battery 200 where the second parallel circuit 135 is eliminated. Assume the case where the second parallel circuit 135 is eliminated. In this case, when the current interruption device 53 is switched to an open state and the switch 133 of the first parallel circuit 130 is switched to a closed state in a state where a no-current state of the assembled battery 60 continues for a predetermined period, only in a case where the battery 50 is connected to the automobile 10 via the external terminals 51, 52, the current I3 flows from the alternator 140 that is an in-vehicle power supply via the external terminal 51 and the first parallel circuit 130, and in a case where the battery 50 is not connected to the automobile 10, the current I3 does not flow through the above path.

Accordingly, the connection state of the battery 50 with the automobile 10 via the external terminals 51, 52 can be determined based on whether or not there is a current I3 that flows in the path from the alternator 140 that is the in-vehicle power supply via the external terminal 51 and the first parallel circuit 130 in a state where the current interruption device 53 is switched from a closed state to an open state and the switch 133 of the first parallel circuit 130 is switched from an open state to a closed state.

The presence or non-presence of the current I3 may be measured by the current sensor 54 that is provided for measuring a current of the assembled battery 60, or may be measured by a dedicated current sensor 210. The presence or non-presence of the current I3 may be detected by detecting a change in voltage associated with the current. For example, a change in voltage may be detected by detecting a change in voltage at a midpoint E of the first parallel circuit 130.
(9) In this embodiment, it is assumed that the automobile 10 is operating during a period that where the drive device such as the engine or the drive motor is operating. The operation period of the automobile 10 may include, in addition to the above operation period, a state where a power supply system of the vehicle is activated during plug-in charging or parking (ACC state), and a state where electricity of the automobile is utilized as an energy storage system during an idling stop (V2H state). That is, in addition to the case where a drive device of a power system such as the engine or the drive motor is operating, a period where the power supply system of the automobile 10 is at least activated may be included in the operation period of the automobile 10.

1. An energy storage apparatus for a moving body, comprising:
an energy storage cell;
an external terminal for connecting the energy storage apparatus to the moving body;
a current interruption device provided to a connection line that connects the energy storage cell and the external terminal, the current interruption device being configured to interrupt a current of the energy storage cell;
a first parallel circuit connected in parallel to the current interruption device and the energy storage cell; and
a control unit,
wherein the first parallel circuit includes a resistor and a switch that is connected to the resistor in series, and
the control unit determines, in a state where the current interruption device is switched to an open state and the switch of the first parallel circuit is brought into a closed state, an electrical connection state of the energy storage apparatus to the moving body based on a current that flows from the moving body via the external terminal and the first parallel circuit.

2. The energy storage apparatus for a moving body according to claim 1, wherein,
in a case where a no-current state of the energy storage cell continues for a predetermined period in a state where the switch of the first parallel circuit is switched to an open state and the current interruption device is switched to a closed state,
the control unit switches the switch of the first parallel circuit into a closed state and switches the current interruption device to an open state, and determines an electrical connection state of the energy storage apparatus to the moving body based on a current that flows from the moving body via the external terminal and the first parallel circuit.

3. The energy storage apparatus for a moving body according to claim 1, further comprising a current sensor within a range from the external terminal to a parallel connection point of the first parallel circuit with respect to a connection line that connects the external terminal and the energy storage cell.

4. The energy storage apparatus for a moving body according to claim 1, further comprising a second parallel circuit that is connected in parallel to the current interruption device, wherein
the second parallel circuit includes a diode where a discharging direction of the energy storage cell is set as a forward direction, and a switch that is connected in series with the diode.

5. The energy storage apparatus for a moving body according to claim 4, wherein
the moving body is a vehicle, and
in a case where a no-current state of the energy storage cell continues for a predetermined period during a period where the vehicle is operating,
the control unit switches the current interruption device to an open state, switches the switch of the first parallel circuit into a closed state, and switches the switch of the second parallel circuit into a closed state, and determines an electrical connection state of the energy storage apparatus to the vehicle based on a current that flows from the vehicle via the external terminal and the first parallel circuit.

6. The energy storage apparatus for a vehicle according to claim 5, wherein the control unit notifies disconnection of the energy storage apparatus to the vehicle when the control unit detects the disconnection of the energy storage apparatus during an operation of the vehicle.

7. The energy storage apparatus for a vehicle according to claim 5, wherein in a case where the control unit detects disconnection of the energy storage apparatus during an operation of the vehicle, the control unit determines that a cable that electrically connects the energy storage apparatus and the vehicle is detached or disconnected.

8. The energy storage apparatus for a vehicle according to claim 5, wherein the control unit determines an operation and a non-operation of the vehicle via communication with the vehicle.

9. The energy storage apparatus for a vehicle according to claim 5, wherein the control unit, in a case where the no-current state of the energy storage cell continues for a predetermined period during an operation of a drive device of the vehicle, switches the current interruption device to an open state, the switch of the first parallel circuit to a closed state, and the switch of the second parallel circuit to a closed state, and determines an electrical connection state of the energy storage apparatus to the vehicle.

10. The energy storage apparatus for a vehicle according to claim 5, wherein a cable that electrically connects the energy storage apparatus to the vehicle is fastened to the external terminal by a bolt.

11. A moving body comprising:
the energy storage apparatus according to claim 1; and
a power supply other than the energy storage apparatus.

12. A method for determining a connection state of an energy storage apparatus for a moving body,
the energy storage apparatus including:
an energy storage cell;
an external terminal for connecting the energy storage apparatus to the moving body;
a current interruption device provided to a connection line that connects the energy storage cell and the external terminal, the current interruption device being configured to interrupt a current of the energy storage cell; and
a first parallel circuit connected in parallel to the current interruption device and the energy storage cell,
the method comprising determining, in a state where the current interruption device is switched to an open state and a switch of the first parallel circuit is switched to a closed state, an electrical connection state of the energy storage apparatus to the moving body based on a current that flows from the moving body via the external terminal and the first parallel circuit.
